(19) United States
(12) Patent Application Publication
(10) Pub. No.: US 2008/0318362 A1
(43) Pub. Date: Dec. 25, 2008

(54) Manufacturing Method of Semiconductor Integrated Circuit Device

(76) Inventors: Chuichi Miyazaki, Akishima (JP); Yoshiyuki Abe, Hinode (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/562,800

(22) PCT Filed: Jul. 16, 2004
(86) PCT No.: PCT/JP2004/010550

§ 371 Date: Dec. 29, 2005

(51) Int. Cl. H01L 21/304

(52) U.S. Cl. 438/113; 257/E21.237

(57) ABSTRACT

After performing rough grinding to the back surface of a semiconductor wafer using the first grinding material (for example, particle size of polish fine powder from #320 to #360) and making the thickness of the semiconductor wafer, for example less than 140 □m, less than 120 □m, or less than 100 □m, the back surface of the semiconductor wafer being performed fine finish grinding using the third grinding material (for example, particle size of polish fine powder from #3000 to #100000), the thickness of the semiconductor wafer becomes, for example less than 100 □m, less than 80 □m, or less than 60 □m, and the relatively thin second crush layer, for example the second crush layer of the thickness of less than 0.5 □m, less than 0.3 □m, or less than 0.1 □m is formed on the back surface of the semiconductor wafer. Thereby, without reducing the die strength of a chip, at the same time permeation of the pollution impurities from the back surface of the semiconductor wafer and further, diffusion of the pollution impurities to the circuit formation surface of the semiconductor wafer are prevented, and the poor characteristic of semiconductor elements is prevented.

### INCORPORATION BY REFERENCE

The present application claims priority from PCT application PCT/JP2004/010550 filed on Jul. 16, 2004, the content of which is hereby incorporated by reference into this application.

### TECHNICAL FIELD

This invention relates to the manufacturing technology of a semiconductor integrated circuit device, and especially relates to the effective technology in the application to the manufacturing of the semiconductor integrated circuit device after formation of a circuit pattern is mostly completed on a semiconductor wafer from the back-grinding to grind the back surface of a semiconductor wafer to the dicing to carve a semiconductor wafer into each chip, and further to the die bonding for a chip to be taken up and mounted on a substrate.

### BACKGROUND ART

For example, in Japanese Unexamined Patent Publication No. 2003-179023, the structure which made, in order to carry out efficiently the back surface grinding processing and etching processing to be carried out to a wafer back surface, the grinder equipment to perform back grinding processing of the back surface of the wafer with which a protection tape was stuck on the circuit formation surface, the back side etching apparatus to perform back side etching processing of the back surface in which back grinding was performed with this grinder equipment, and the transfer equipment for the wafer to be transferred on a dicing tape and to make the protection tape peel from the wafer, in-line is indicated.

For example, in Japanese Unexamined Patent Publication No. 2003-133395 (US Patent Publication No. 2003/077854), the technology, using the jig for wafer fixation, providing the outer frame and the rubber membrane object, being provided in this outer frame, to fluctuate volume performing shape distortion by supplying air to an inside, considered as the structure, when the rubber membrane increases volume, to perform shape distortion so that the tape located between the wafer and the rubber membrane may push and press towards outside from the center and towards a wafer gradually, carrying out an attaching step, a back-grinding step, a tape replacing and sticking again step, a picking-up step, and a die-bonding step, is indicated.

For example, in Japanese Unexamined Patent Publication No. 2003-152058 (US Patent Publication No. 2003/088959), the wafer transfer equipment providing the first ultraviolet-rays irradiation unit to irradiate ultraviolet rays to a protection tape, the positioning unit to position a wafer, the mounting unit uniting a ring frame, the protection tape peeling unit to peel the protection tape from the wafer surface, and the second ultraviolet-rays irradiation unit to irradiate ultraviolet rays to a dicing tape, is indicated.

### DISCLOSURE OF THE INVENTION

The manufacturing process till die bonding which performs the back-grinding of the semiconductor wafer, individually separates this semiconductor wafer for each chip by dicing, and mounts the chip individually separated on a substrate advances as the following.

First, after sticking an adhesive tape on the circuit formation surface of a semiconductor wafer, by equipping a grinder equipment with the semiconductor wafer and grinding the back surface of a semiconductor wafer pressing the rotating grinding material, the thickness of the semiconductor wafer is made thin to the predetermined thickness (back-grinding step). Then, with a wafer mounting equipment, the back surface of the semiconductor wafer is stuck on the dicing tape fixed to the ring-like frame, and an adhesive tape is peeled from the circuit formation surface of the semiconductor wafer (wafer mounting step).

Next, the semiconductor wafer is cut along predetermined scribe-lines, and the semiconductor wafer is individually separated to each chip (dicing step). As for the chip individually separated, the back surface is pushed and pressed by the pushing-up pin via the dicing tape, and, thereby, the chip peels from the dicing tape. The collet is located at the upper part opposing the pushing-up pin, and the chip peeled is adsorbed by the collet and held (picking-up step). Then, the chip held at the collet is transported to a substrate, and is bonded at the predetermined position on the substrate (die-bonding step).

By the way, while the miniaturization and thinning of an electric device progress, thinning of the chip mounted in it is demanded. The laminated type semiconductor integrated circuit device to laminate and mount a plurality of chips in one package is developed in recent years, and the demand to the thinning of a chip is increasing more and more. For this reason, at the back-grinding step, grinding to make the thickness of a semiconductor wafer, for example less than 100 □m is performed. The back surface of the ground semiconductor wafer includes an amorphous layer/a poly-crystalline material layer/a micro crack layer/an atomic level distortion layer (stress gradual shift layer)/a pure crystal layer, and among these an amorphous layer/a poly-crystalline material layer/a micro crack layer is a crush layer (or crystal defective layer). The thickness of this crush layer is about 1-2 □m, for example.

If the above-mentioned crush layer is in the back surface of a semiconductor wafer, the problem that the die strength (the stress value at the time of a chip breaking when a simple bending stress is applied to the chip) of the chip individually separated from the semiconductor wafer falls will arise. The drop of this die strength appears notably in the chip of less than 100 □m in thickness. Then, the drop of the die strength of a chip is prevented by performing stress relief following a back-grinding, removing a crush layer, and making the back surface of a semiconductor wafer into a specular surface. In stress relief, a dry-polishing method, the CMP (Chemical Mechanical Polishing) method, or a chemical-etching method is used, for example. Namely, in stress relief, the polishing method removing the crush layer (in connection with it, an atomic level distortion layer generates in an interface with a single crystal) generated unavoidably in grinding by a fixed abrasive with grinding or polishing of a non-fixed abrasive system, that is, with a floating abrasive particle and a scouring pad (a floating abrasive particle is not used in a dry-polishing), the wet etching by chemical fluid, etc. are applied.

However, if the crush layer of the back surface of a semiconductor wafer is removed, heavy metal impurities, such as the pollution impurities adhering to the back surface of the semiconductor wafer, for example, copper, (Cu), iron (Fe), nickel (Ni), or chromium (Cr), will permeate into a semiconductor wafer easily. Pollution impurities are mixed in all semiconductor fabrication machines and equipments, such as gas piping and heater wires, and process gas can also serve as a pollution source of pollution impurities. The pollution impurities which permeated from the back surface of a semiconductor wafer diffuse the inside of a semiconductor wafer further, and can be drawn near to the crystal defect near the circuit formation surface. The pollution impurities diffused even near the circuit formation surface, for example form the trapping level of a carrier into a forbidden band, and, the pollution impurities dissolved as solid to the silicon oxide/silicon interface, for example make an interface state increase. As a result, the poor characteristic of the semiconductor element resulting from pollution impurities arises, and a drop of the manufacture yield of semiconductor products takes place. For example, in the flash memory which is a semiconductor nonvolatile memory, the bad sector at the time of Erase/Write resulting from pollution impurities increases, and the defective characteristic occurs, with the number of relief sectors being lacking. In the general DRAM (Dynamic Random Access Memory) and pseudo-SRAM (Static Random Access Memory) for example, a defectiveness of the leak system, such as degradation of the Refresh characteristic and the Self Refresh characteristic resulting from pollution impurities, occurs. Poor Data Retention occurs in the memory of the flash system.

That is, by this stress relief, although the die strength of a chip is securable with the stress relief after a back-grinding, since a crush layer is lost, the gettering effect over invasion of the pollution impurities from the back surface of a semiconductor wafer falls. If diffusion of pollution impurities goes to near a circuit formation surface, the characteristic of a semiconductor element may be changed and the operation may become poor. If the crush layer in the back surface of the semiconductor wafer is left, permeation of the pollution impurities which adhered to the back surface of the semiconductor wafer can be stopped by this crush layer, but a drop of the die strength of a chip cannot be prevented.

One purpose of one invention indicated in the embodiment is to offer the technology in which a drop of the manufacture yield of the semiconductor products resulting from pollution impurities can be suppressed.

One purpose of one invention indicated in the embodiment is to offer the technology which can prevent a drop of the die strength of a chip and for which improvement in the manufacture yield of semiconductor products can be realized.

The above and other purposes and the new feature of the invention will become clear from description and the accompanying drawings of the specification.

That is, in one invention indicated by the present application, when a semiconductor wafer is made a thin film, the back surface of a semiconductor wafer is ground by the grinding material which has a fixed abrasive so that the relatively thin crush layer with a gettering function of less than 0.5 □m, less than 0.3 □m, or less than 0.1 □m in thickness may be formed in the back surface, for example, and the die strength after making a chip by dividing or mostly dividing a semiconductor wafer (not limited to dicing with a rotation blade. For example, division by laser etc. is possible), may be secured.

In other one invention indicated by the present application, when a semiconductor wafer is made a thin film, removing the crush layer (stress relief) formed by grinding the back surface of the semiconductor wafer by the grinding material which has a fixed abrasive, the die strength after making a chip by dividing or mostly dividing the semiconductor wafer, is secured, then, the relatively thin crush layer with a gettering function of less than 0.5 □m, less than 0.30 □m, or less than 0.1 □m in thickness is newly formed in the back surface of the semiconductor wafer, for example.

According to the above-mentioned invention, while securing the die strength after making a chip by dividing or mostly dividing a semiconductor wafer made a thin film, preventing the permeation of the pollution impurities from the back surface of the semiconductor wafer, and further preventing the diffusion of the pollution impurities to the circuit formation surface of the semiconductor wafer, the generation of the poor characteristic of a semiconductor element can be suppressed. A process is easy in the case where a crush layer is formed by the grinding agent which has a fixed abrasive. On the other hand, in the case where a crush layer is newly formed after stress relief, the die strength of a chip can be raised.

It will be as follows, if other typical things are divided into a clause and explained among inventions indicated in a present application below.

1. A manufacturing method of a semiconductor integrated circuit device, comprising the steps of:

(a) forming a circuit pattern on a first main surface of a semiconductor wafer that has' a first thickness;

(b) making the semiconductor wafer a second thickness by grinding a second main surface of the semiconductor wafer using a first grinding material which has a fixed abrasive;

(c) making the semiconductor wafer a fourth thickness and forming a second crush layer in the second main surface of the semiconductor wafer by grinding the second main surface of the semiconductor wafer using a third grinding material which has a fixed abrasive a diameter of a particle of which is smaller than the first grinding material; and

(d) individually separating the semiconductor wafer to a chip by dicing the semiconductor wafer.

2. A manufacturing method of a semiconductor integrated circuit device, comprising the steps of:

(a) forming a circuit pattern on a first main surface of a semiconductor wafer that has a first thickness;

(b) making the semiconductor wafer a second thickness by grinding a second main surface of the semiconductor wafer using a first grinding material which has a fixed abrasive;

(c) making the semiconductor wafer a third thickness and forming a first crush layer in the second main surface of the semiconductor wafer by grinding the second main surface of the semiconductor wafer using a second grinding material which has a fixed abrasive a diameter of a particle of which is smaller than the first grinding material;

(d) removing the first crush layer of the second main surface of the semiconductor wafer;

(e) forming a third crush layer in the second main surface of the semiconductor wafer; and

(f) individually separating the semiconductor wafer to a chip by dicing the semiconductor wafer.

It will be as follows, if other typical things are divided into a clause and explained among inventions indicated in a present application below.

1. A manufacturing method of a semiconductor integrated circuit device, comprising the steps of:

(a) forming a circuit pattern on a first main surface of a semiconductor wafer that has a first thickness;

(b) making the semiconductor wafer a second thickness by grinding a second main surface of the semiconductor wafer using a first grinding material which has a fixed abrasive;

(c) making the semiconductor wafer a third thickness by grinding the second main surface of the semiconductor wafer using a second grinding material which has a fixed abrasive a diameter of a particle of which is smaller than the first grinding material; and

(d) individually separating the semiconductor wafer to a chip by dicing (separating into a chip section) the semiconductor wafer;

wherein a particle size of a polish fine powder of the second grinding material is #3000 to #100000.

2. A manufacturing method of a semiconductor integrated circuit device, comprising the steps of:

(a) forming a circuit pattern on a first main surface of a semiconductor wafer that has a first thickness;

(b) making the semiconductor wafer a second thickness by grinding a second main surface of the semiconductor wafer using a first grinding material which has a fixed abrasive;

(c) making the semiconductor wafer a third thickness and forming a first crush layer in the second main surface of the semiconductor wafer by grinding the second main surface of the semiconductor wafer using a second grinding material which has a fixed abrasive a diameter of a particle of which is smaller than the first grinding material;

(d) removing the first crush layer of the second main surface of the semiconductor wafer;

(e) forming a second crush layer in the second main surface of the semiconductor wafer; and

(f) individually separating the semiconductor wafer to a chip by dicing (separating into a chip section) the semiconductor wafer.

3. One invention indicated by the present application, in a manufacturing method of a semiconductor integrated circuit device, by using grinding material a main diameter of a fixed abrasive of which is about 4 to 6 microns, or grinding material finer than it for the last back surface grinding, leaves a non-perfect crystal layer to the back surface, and uses as an impurities trap layer.

1. In the above-mentioned clause 3, the main diameter of the fixed abrasive is almost 2 microns to 4 microns or finer than it.

2. In the above-mentioned clause 3, the main diameter of the fixed abrasive is almost around 0.5 micron or finer than it.

3. In the above-mentioned clause 3, the main diameter of the fixed abrasive is almost 2 microns or finer than it.

4. In the above-mentioned clause 3, the main diameter of the fixed abrasive is almost 1 micron or finer than it.

5. In the above-mentioned clause 3, the main diameter of the fixed abrasive is almost 0.5 micron or finer than it.

6. In a manufacturing method of a semiconductor integrated circuit device, after back surface grinding, one invention indicated by the present application removes a crush layer (the first crush layer) substantially once, and again newly adds a crush layer (the second crush layer).

7. In the above-mentioned clause 6, the thickness of the second crush layer is thinner than the thickness of the first crush layer.

8. In the above-mentioned clause 6 or 7, the first crush layer and the second crush layer are generated by different way.

9. In the above-mentioned clause 6 or 7, the first crush layer and the second crush layer are generated by the same way (for example, formed by grinding using the fixed abrasive of different particle diameter).

### BRIEF DESCRIPTION OF THE DRAWINGS

FIG. 1 is a flowchart of the manufacturing method of a semiconductor integrated circuit device;

FIG. 2 is a principal part side view in the manufacturing process of a semiconductor integrated circuit device;

FIG. 3 is a principal part expanded sectional view of the back side portion of a semiconductor wafer;

FIG. 4 is a principal part expanded sectional view of the back side portion of a semiconductor wafer;

FIGS. 5 (a), (b), and (c) are the graphical representation showing the relation between the die strength of a chip, and the finish roughness of the back surface of a semiconductor wafer, a graphical representation showing the relation between the finish roughness of the back surface of a semiconductor wafer, and the diameter of a particle of grinding material, and a graphical representation showing the relation between the thickness of a crush layer, and the diameter of a particle of grinding material, respectively;

FIG. 6 is a principal part side view in the manufacturing process of the semiconductor integrated circuit device following FIG. 2;

FIG. 7 is a principal part side view in the manufacturing process of the semiconductor integrated circuit device following FIG. 6;

FIG. 8 is a principal part side view in the manufacturing process of the semiconductor integrated circuit device following FIG. 7;

FIG. 9 is a principal part side view in the manufacturing process of the semiconductor integrated circuit device following FIG. 8;

FIG. 10 is a principal part side view in the manufacturing process of the semiconductor integrated circuit device following FIG. 9;

FIG. 11 is a principal part side view in the manufacturing process of the semiconductor integrated circuit device following FIG. 10;

FIG. 12 is a principal part side view in the manufacturing process of the semiconductor integrated circuit device following FIG. 11;

FIG. 13 is a principal part side view in the manufacturing process of the semiconductor integrated circuit device following FIG. 12;

FIG. 14 is a principal part side view in the manufacturing process of the semiconductor integrated circuit device following FIG. 13;

FIG. 15 is a principal part side view in the manufacturing process of the semiconductor integrated circuit device following FIG. 14;

FIG. 16 is an explanatory diagram of the consistent processing unit used from back-grinding to wafer mounting of the manufacturing method of a semiconductor integrated circuit device;

FIG. 17 is a flowchart of the manufacturing method of a semiconductor integrated circuit device;

FIGS. 18(a), (b), and (c) are explanatory diagrams of equipment which illustrate the stress relief by a dry-polishing method, a CMP method, and a spin-etching method in the manufacturing method of a semiconductor integrated circuit device, respectively;

FIG. 19 is a principal part expanded sectional view of the back side portion of a semiconductor wafer;

FIG. 20 is an explanatory diagram of other consistent processing unit used from back-grinding to wafer mounting of the manufacturing method of a semiconductor integrated circuit device; and

FIG. 21 is a principal part sectional view of a fixed abrasive.

### BEST MODE FOR CARRYING OUT THE INVENTION

Hereafter, the embodiments of the invention are explained in detail based on drawings. In the below-described embodiments, a description will be made after divided in plural sections or in plural embodiments if necessary for convenience's sake. These plural sections or embodiments are not independent each other, but in a relation such that one is a modification example, details or complementary description of a part or whole of the other one unless otherwise specifically indicated. In the below-described embodiments, when a reference is made to the number of elements (including the number, value, amount and range), the number is not limited to a specific number but can be greater than or less than the specific number unless otherwise specifically indicated or principally apparent that the number is limited to the specific number. Moreover in the below-described embodiments, it is needless to say that the constituting elements (including element steps) are not always essential unless otherwise specifically indicated or principally apparent that they are essential. Similarly, in the below-described embodiments, when a reference is made to the shape or positional relationship of the constituting elements, that substantially analogous or similar to it is also embraced unless otherwise specifically indicated or principally apparent that it is not. This also applies to the above-described value and range. In all the drawings for describing the embodiments, like members of a function will be identified by like reference numerals and overlapping descriptions will be omitted. In the drawings used in the below-described embodiments, even a plan view is sometimes hatched for facilitating understanding of it.

In the following embodiments, when calling it a semiconductor wafer, it is mainly concerned with Si (silicon) single crystal wafer, but not only it but a SOI (Silicon on Insulator) wafer, the insulated film substrate for forming an integrated circuit on it, etc. shall be pointed out. The form shall also contain not only a round shape or an almost circular shape but a square, a rectangle, etc. When mentioning the member of gas, a solid, or a liquid, an ingredient specified there is considered to be one of main ingredients, but except for the case where it writes clearly such especially or the case of being theoretically clear, other ingredients are not excepted.

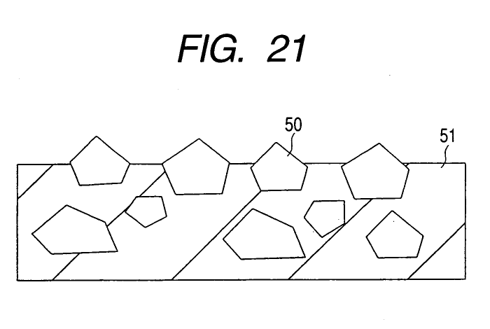

The representative example of the grinding material having a fixed abrasive is what is called a grinding wheel, and is considered as the structure having a plurality of fine abrasive particles which are grinding material and the binder combining the plurality of abrasive particles. An example of the principal part sectional view of a fixed abrasive is shown in FIG. 21. Mark 50 shows the abrasive particle including a diamond etc., and mark 51 shows binder. There are mixtures of such as feldspar and meltable clay, a good synthetic resin (things other than a synthetic rubber or crude rubber), etc. in binder. At the grinding step using the grinding material having a fixed abrasive, the abrasive particle is being fixed, and since mechanical power is added to the surface (surface to be ground) where a semiconductor wafer is ground, a crush layer is formed in the surface of a semiconductor wafer to be ground. One grinding processing of the embodiments is a thing adapting this, and the crush layer is made to be formed in the surface of a semiconductor wafer to be ground well using the grinding material having a fixed abrasive. There is a floating abrasive particle to a fixed abrasive. A floating abrasive particle is the polish powder contained in slurry etc., and since the abrasive particle is not being fixed in the case where this floating abrasive particle is used, it is common that a crush layer is not formed in the polished surface of a semiconductor wafer. What is called polishing is classified into the polish using this floating abrasive particle for convenience in the point which does not form a crush layer including the case where, it grinds only with abrasive cloth (dry-polishing).

### EMBODIMENT 1

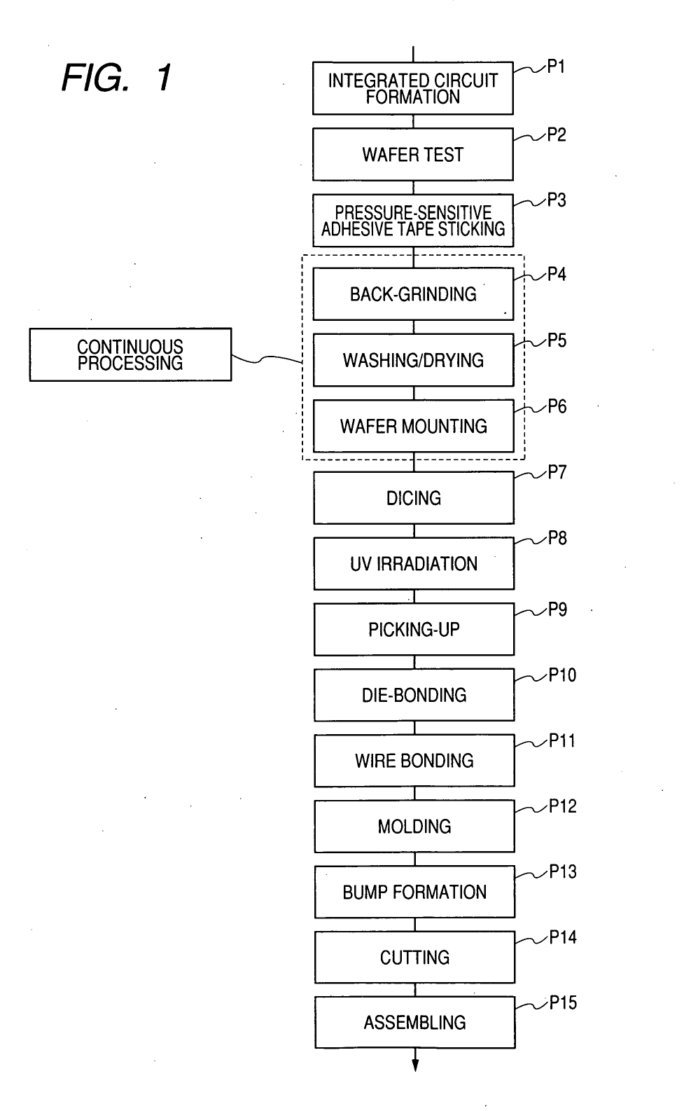

The manufacturing method of the semiconductor integrated circuit device by the Embodiment 1 is explained in order of a step using FIG. 1 to FIG. 15.

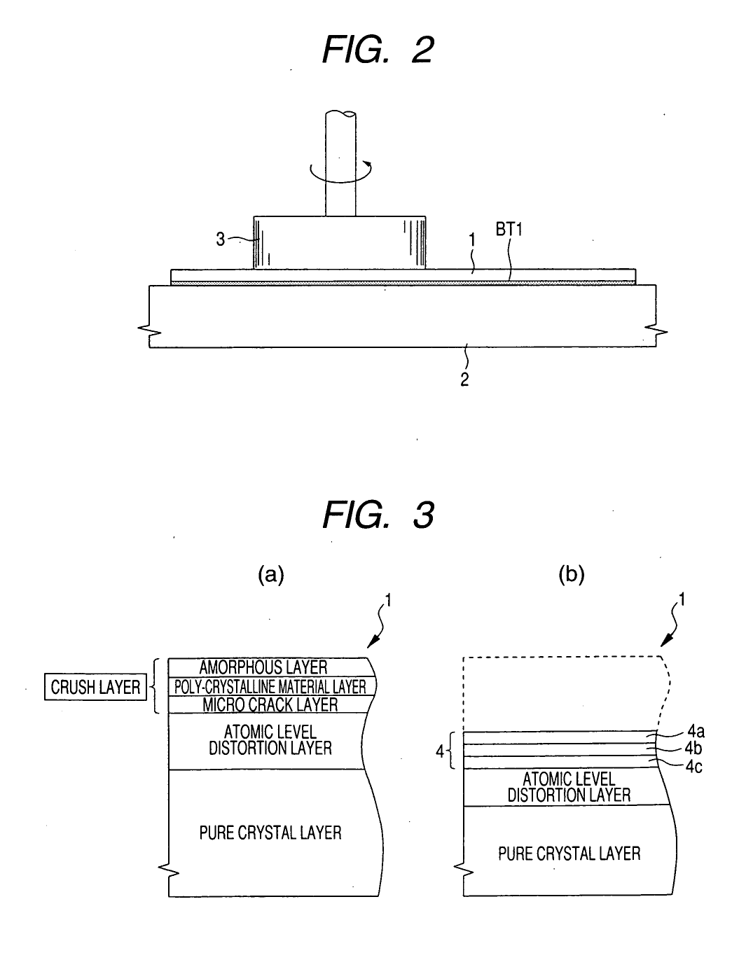

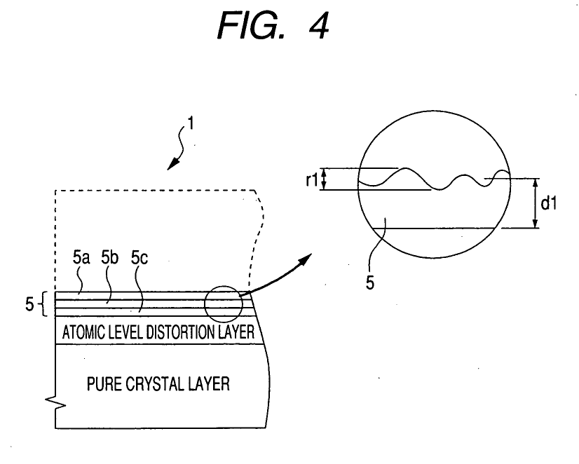

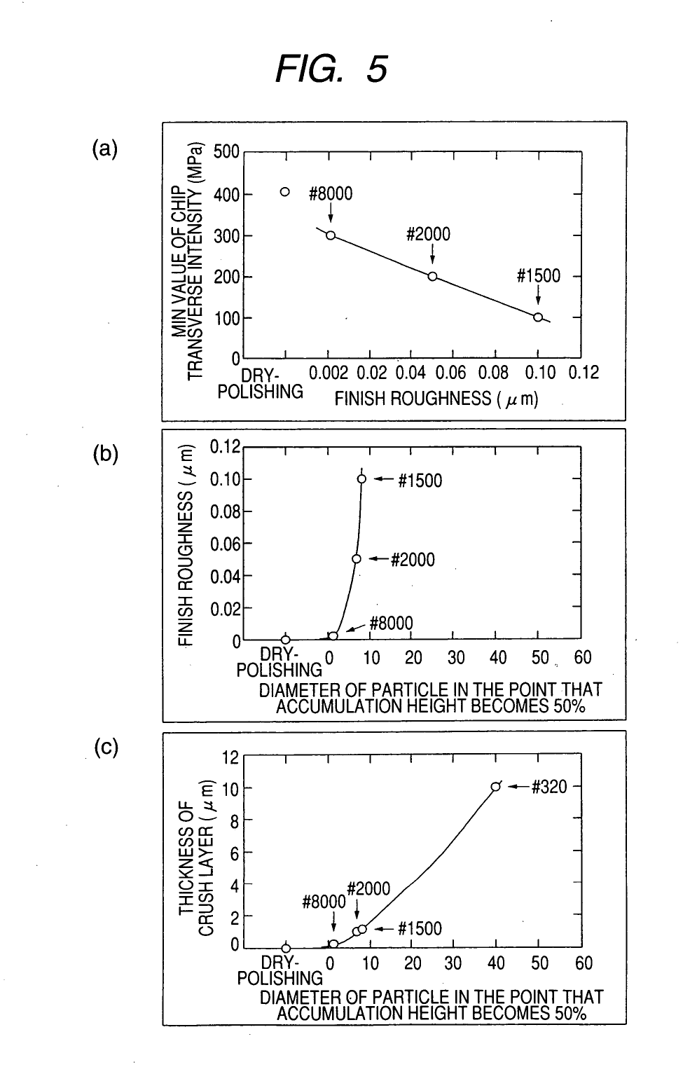

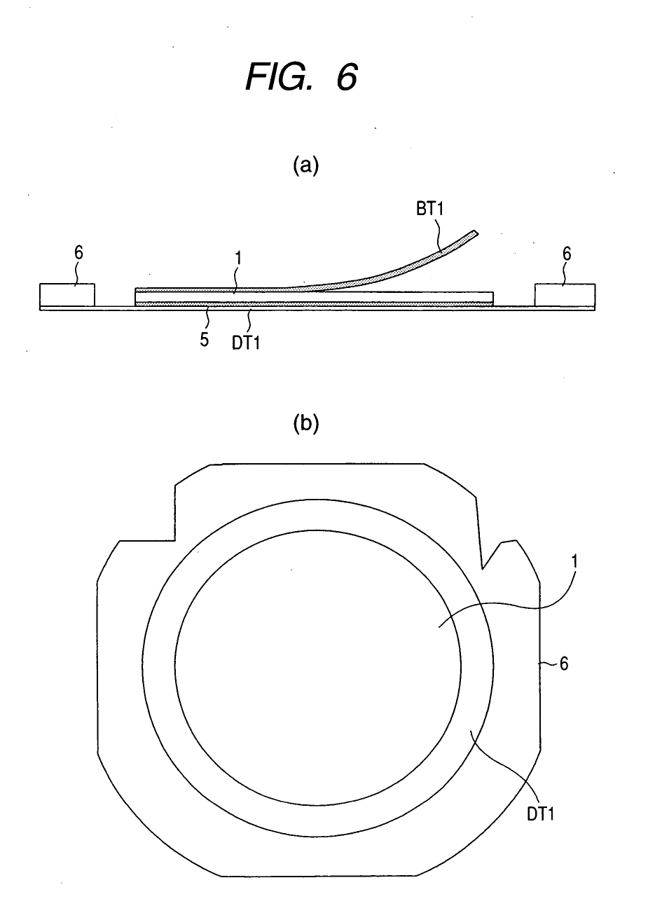

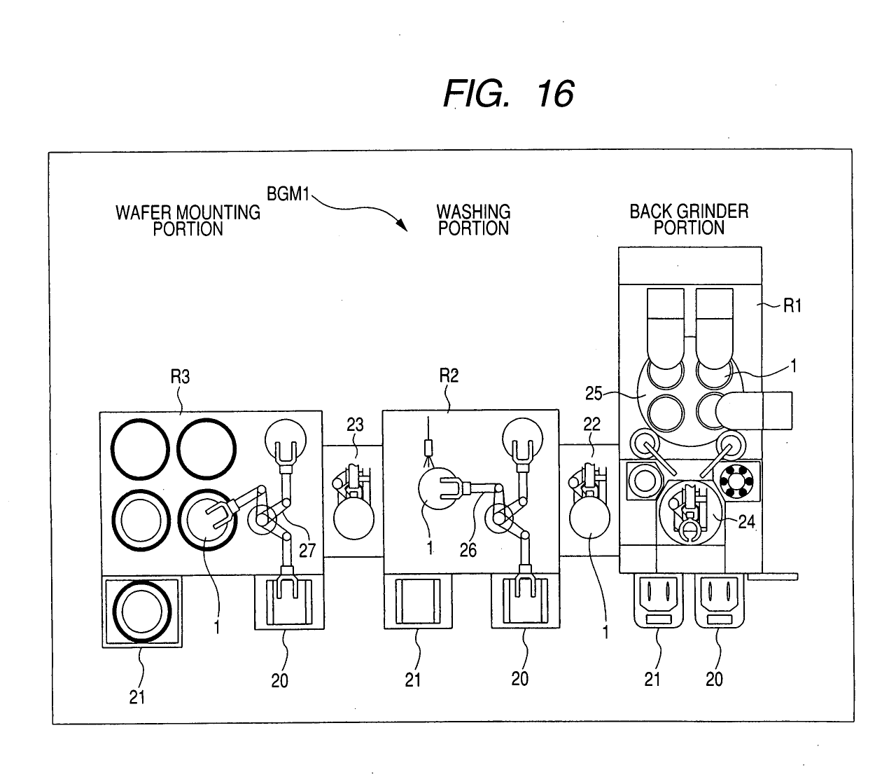

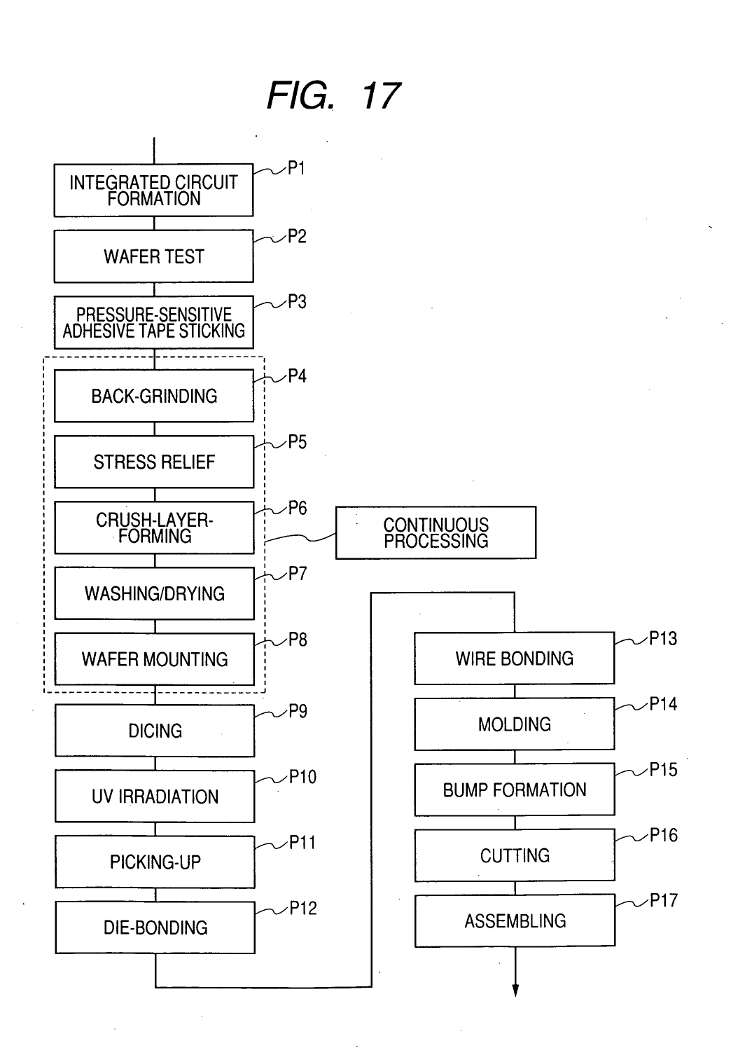

FIG. 1 is a flowchart of the manufacturing method of a semiconductor integrated circuit device; FIG. 2 and from FIG. 6 to FIG. 15 are principal part side views in the manufacturing process of a semiconductor integrated circuit device; FIG. 3 and FIG. 4 are principal part expanded sectional views of the back side portion of a semiconductor integrated circuit device; and FIG. 5(a), (b), and (c) are the graphical representation showing the relation between the die strength of a chip, and the finish roughness of the back surface of a semiconductor wafer, a graphical representation showing the relation between the finish roughness of the back surface of a semiconductor wafer, and the diameter of a particle of grinding material, and a graphical representation showing the relation between the thickness of a crush layer, and the diameter of a particle of grinding material, respectively. FIG. 16 is an explanatory diagram of the consistent processing unit used from back-grinding to wafer mounting. The following explanation explains each step, such as from the back-grinding after forming a circuit pattern on a semiconductor wafer to the die bonding which connects the chip individually separated on the substrate, and further the molding which protects laminated two or more chips by resin etc.

First, an integrated circuit is formed in the circuit formation surface (the first main surface) of a semiconductor wafer (integrated circuit formation step P1 of FIG. 1). A semiconductor wafer includes a silicon single crystal, the diameter is 300 mm and the thickness (the first thickness) is more than 700 □m (value at the time of the input to a wafer step), for example.

Next, the good and the defect of each chip made on the semiconductor wafer are judged (wafer test step P2 of FIG. 1). First, a semiconductor wafer is laid in the stage for measurement, and if a probe is contacted to the electrode pad of an integrated circuit and a signal waveform is inputted into it from an input terminal, a signal waveform will be outputted from an output terminal. When a tester reads this, the good and the defect of a chip are judged. Here, the probe card which has arranged the probes according to all the electrode pads of an integrated circuit is used, and from the probe card, the signal wire corresponding to each probe has come out, and it connects with the tester. Marking which shows a defect is struck to the chip judged to be defective.

Next, an adhesive tape (Pressure-Sensitive adhesive tape) is stuck on the circuit formation surface of a semiconductor wafer (adhesive tape sticking step P3 of FIG. 1). Here, a self-peeling type tape, i.e., UV hardening type (UV cure type), a heat hardening type, or EB hardening type is sufficient as an adhesive tape, and a non-UV hardening type pressure-sensitive adhesive tape, namely, the common adhesive tape (non-self peeling type tape) which is not UV hardening type, a heat hardening type, or EB hardening type, either is sufficient. In the case of a non-self peeling type tape, although self-peeling property cannot be used, there is the strong point that the change of the write-in information on memory system circuits, such as a nonvolatile memory, a characteristic shift, and the undesirable change of surface properties of a surface protection member or wiring insulation members, etc. such as a polyimide layer, generated in the case where ultraviolet ray (energy ray irradiation or heating) is irradiated to the circuit formation surface of a wafer, are avoidable.

Below, the example of a non-self peeling type tape is explained. The adhesive is applied to the adhesive tape and this sticks an adhesive tape with the circuit formation surface of a semiconductor wafer. An adhesive tape uses polyolefin as a base material, for example, the adhesive of an acrylics system is applied, and the peeling material including polyester on it further is stuck. Peeling material is a mold-releasing paper, for example, peeling material is removed and an adhesive tape is stuck on a semiconductor wafer. The thickness of an adhesive tape is 0.130 to 150 □m, and adhesive power is 20 to 30 g/20 mm (it expresses as the strength at the time of peeling of the tape of 20 mm width), for example. There is no peeling material and the adhesive tape about which mold-releasing-processing is done to the back surface of the substrate may be used.

Next, the back surface (the surface opposite to the circuit formation surface, the second main surface) of the semiconductor wafer shall be ground to the predetermined thickness of the semiconductor wafer, for example, less than 100 □m, less than 80 □m, or less than 60 □m, and a crush layer is formed in the back surface of the semiconductor wafer (back-grinding step P4 of FIG. 1). In this back-grinding, rough grinding, finish grinding, and fine finish grinding which are explained below are performed one by one.

First, as shown in FIG. 2, the back surface of semiconductor wafer 1 is rough-ground. After transporting semiconductor wafer 1 to a grinder equipment and performing vacuum adsorption of the circuit formation surface of semiconductor wafer 1 at chuck table 2, by performing rough-grinding pressing the rotating first grinding material 3 (for example, particle-size of polish fine powder from #320 to #360: particle size # showing the diameter of polish or a grinding abrasive particle corresponds to the size of the eye of the sieve at the time of sifting the diamond grindstone at the time of manufacturing a grinding wheel etc. In other words, it corresponds to the diameter of main abrasive particles. If an example is shown, the particle diameter of #280 is about 100 □m, the particle diameter of #360 is about 40 to 60 □m, the particle diameter of #2000 is about 4 to 6 □m, the particle diameter of #4000 is about 2 to 4 □m, and the particle diameter of #8000 is about 0.2 □m. The present application indicates the diameter of an abrasive particle based on this. There is a JIS standard about less than or equal to #320.) to the back surface of semiconductor wafer 1, the thickness of semiconductor wafer 1 is made to decrease to the predetermined thickness (the second thickness). The first grinding material is the grinding material having a fixed abrasive, and by this rough grinding, semiconductor wafer 1 is ground by, for example, about 600 to 700 □m. As for the second thickness of semiconductor wafer 1 which remains by this rough grinding, less than 140 □m, for example is considered to be a suitable range (naturally depending on other conditions, not limited to this range). Although less than 120 □m can be considered as a range suitable for mass production, it is thought that the range less than 100 m is the most preferred. Since adhesive tape BT1 is stuck on the circuit formation surface of semiconductor wafer 1, an integrated circuit is not destroyed. In a general process, it is thought that more than or equal to #100 and less than #700 is suitable for the particle size range of the above-mentioned first grinding material.

Then, the back surface of semiconductor wafer 1 is performed finish grinding. After performing vacuum adsorption of the circuit formation surface of semiconductor wafer 1 here at a chuck table using the same grinder equipment as the FIG. 2, by performing finish grinding pressing the rotating second grinding material (for example, particle size of polish fine powder from #1500 to #2000) to the back surface of semiconductor wafer 1, the distortion of the back surface of semiconductor wafer 1 produced at the time of the above-mentioned rough grinding is removed, and simultaneously, the thickness of semiconductor wafer 1 is made to decrease to the predetermined thickness (the third thickness). The second grinding material is the grinding material having a fixed abrasive, and by this finish grinding, the semiconductor wafer 1 is ground by, for example, about 25 to 40 □m. As for the third thickness of semiconductor wafer 1 which remains by this finish grinding, less than 110 □m, for example is considered to be a suitable range (naturally depending on other conditions, not limited to this range). Although less than 90 □m can be considered as a range suitable for mass production, it is thought that the range of less than 70 □m is the most preferred.

In FIG. 3 (a), the principal part expanded sectional view of the back side portion of semiconductor wafer 1 performed rough grinding using the above-mentioned first grinding material is shown, and in this FIG. (b), the principal part expanded sectional view of the back side portion of semiconductor wafer 1 performed finish grinding using the above-mentioned second grinding material is shown. In rough grinding, an atomic level distortion layer and a crush layer (an amorphous layer/a poly-crystalline material layer/a micro crack layer) are formed on the pure crystal layer of the back surface of semiconductor wafer 1. Although, also in finish grinding, an atomic level distortion layer and a crush layer (an amorphous layer 4a/a poly-crystalline material layer 4b/a micro crack layer 4c; the first layer) 4 are formed on the pure crystal layer of the back surface of semiconductor wafer 1, the thickness of a pure crystal layer, an atomic level distortion layer, and the first crush layer 4 becomes thinner than the thickness of the pure crystal layer, an atomic level distortion layer, and a crush layer after rough grinding, respectively. As for the thickness of this first crush layer 4, less than 2 □m, for example is considered to be a suitable range (naturally depending on other conditions, not limited to this range). Although less than 10m can be considered as a range suitable for mass production, it is thought that the range of less than 0.50m is the most preferred.

Then, the back surface of semiconductor wafer 1 is performed fine finish grinding. After performing vacuum adsorption of the circuit formation surface of semiconductor wafer 1 here at a chuck table using the same grinder equipment as the FIG. 2, by performing fine finish grinding pressing the rotating third grinding material to the back surface of semiconductor wafer 1, the thickness of semiconductor wafer 1 is made to decrease to the predetermined thickness (the fourth thickness). The third grinding material is also grinding material having a fixed abrasive, and semiconductor wafer 1 is ground by, for example about 3 to 5 □m by this fine finish grinding. As for the fourth thickness of semiconductor wafer 1 which remains by this fine finish grinding, less than 100 □m, for example is considered to be a suitable range (naturally depending on other conditions, not limited to this range). Although less than 80 m can be considered as a range suitable for mass production, it is thought that the range of less than 60 □m is the most preferred. As for the particle size of the polish particle of the above-mentioned third grinding material, from #3000 to #100000, for example is considered to be a suitable range (naturally depending on other conditions, not limited to this range). Although #4000 to #50000 can be considered as a range suitable for mass production, it is thought that the range of #5000 to #20000 is the most preferred. In the Embodiment 1, #8000 or more than it is used, for example. While the minimum of the particle size of the polish particle of this third grinding material is decided in consideration of the die strength of a chip, that maximum is decided in consideration of the gettering effect.

As shown in FIG. 4, in the above-mentioned fine finish grinding, an atomic level distortion layer and the second crush layer (an amorphous layer 5a/a poly-crystalline material layer 5b/a micro crack layer 5c; the second layer) 5 are formed on the pure crystal layer of the back surface of semiconductor wafer 1, and each thickness of an atomic level distortion layer and the second crush layer 5 is formed more thinly than the thickness of the atomic level distortion layer and the first crush layer 4 after finish grinding, respectively. If pollution impurities, for example, heavy metal impurities etc., adhere to the back surface of semiconductor wafer 1 in the case where a pure silicon crystal structure portion is exposed to the back surface of semiconductor wafer 1, for example, they will infiltrate into semiconductor wafer 1 easily. The pollution impurities which infiltrated into semiconductor wafer 1 diffuse the inside of semiconductor wafer 1, and reach to the circuit formation surface of semiconductor wafer 1, and there is a problem of causing the poor characteristic of the semiconductor element formed in the circuit formation surface. So, in the Embodiment 1, it dares form the second crush layer 5 on the back surface of semiconductor wafer 1, and pollution impurities are made to be captured by the second crush layer 5. Thereby, permeation and diffusion of the pollution impurities to semiconductor wafer 1 can be suppressed. Also in heavy metals, as for Cu, since the diffusion coefficient being 6.8×10⁻²/sec (at 150° C.) and high as compared with the diffusion coefficient (for example, the diffusion coefficient of Fe is 2.8×10⁻¹³/sec (at 150° C.)) of other heavy metals, and it being easy to reach to the circuit formation surface of semiconductor wafer 1, it is thought that it is one of the main pollution impurities which cause the poor characteristic of a semiconductor element. The adhesion material layer of a dicing tape and the adhesion material layer for die bonding can be mentioned as the source of invasion of this Cu, for example. In these adhesion material layers, since a little Cu may be mixing and these adhesion material layers moreover touch semiconductor wafer 1 or the back surface of a chip directly with various impurities and foreign substances (fillers), permeation of Cu is easy.

By the way, as shown, for example in FIG. 5 (a), as the finish roughness of the back surface of semiconductor wafer 1 becomes small, that is, as the particle size of the polish fine powder of grinding material (for example, refer to Japanese Industrial Standards JISR6001) becomes large, the min value of the chip die strength becomes large, and when specular surface finish of the back surface of semiconductor wafer 1 is performed, for example by dry-polishing, the min value of the chip die strength turns into maximum. This is because, as the particle size of the polish fine powder of the grinding material becomes large, the diameter of a particle of the diamond particles of the grindstone adhering to the grinding material becomes small and the roughness of the back surface (finish surface) of semiconductor wafer 1 becomes small as are shown in FIG. 5 (b). If it says further, as shown in FIG. 5 (c), when the roughness of the above-mentioned finish surface becomes small, the thickness of the crush layer will become thin and this will bring about improvement in the die strength of a chip. However, as the thickness of the above-mentioned crush layer with the gettering effect becomes thin, the gettering effect falls, and since, when specular surface finish of the back surface of semiconductor wafer 1 is performed by a dry-polishing, for example, this gettering effect is lost, pollution impurities permeate from the back surface of semiconductor wafer 1, they spread to the circuit formation surface of semiconductor wafer 1, and the poor characteristic of a semiconductor element occurs. For this reason, in the fine finish grinding using the third grinding material, it is required to choose the thickness of the second crush layer 5 and the finish roughness which can make the die strength compatible to some extent with the gettering effect of a chip.

Based on these things, as for the thickness of the above-mentioned second crush layer 5, less than 0.5 □m (that is, it is more advantageous to be comparatively thicker in order to secure the die strength of a chip) is considered to be a suitable range, for example (naturally depending on other conditions, not limited to this range). Although less than 0.3 □m can be considered as a range suitable for mass production, it is thought that the range of less than 0.1 □m (it is because it is satisfactory if it is more than the lower limit which can prevent permeation and diffusion of pollution impurities) is the most preferred. The thickness of the second crush layer 5 is the thickness (for example, d1 shown in FIG. 4) of the average which measured the thickness of the second crush layer 5 in two or more points in semiconductor wafer 1 (for example, five points or ten points), for example using the film-thickness-measurement meter, and was calculated from the average value of the two or more points (for example, five points or ten points) here.

As for the finish roughness (for example, peak magnitude of the surface of the second crush layer 5) of the above-mentioned second crush layer 5, less than 0.1 □m, for example, is considered to be a suitable range. Although less than 0.05 □m can be considered as a range suitable for mass production, it is thought that the range of less than 0.01 □m is the most preferred. Here, the finish roughness of the second crush layer 5 is the roughness of the average which measured the peak magnitude (for example, r1 shown in FIG. 4) of the surface of the second crush layer 5 in two or more points in semiconductor wafer 1 (for example, five points or ten points), for example using the surface roughness meter, and was calculated from the average value of the two or more points (for example, five points or ten points). The finish roughness by dry-polishing is almost equivalent to 0.0001 □m, for example.

Thus, by grinding the thickness of semiconductor wafer 1 to, for example less than 100 □m, less than 80 m, or less than 60 m by the above-mentioned back-grinding, and forming the second crush layer 5 of relatively thin thickness, namely the second crush layer 5 of, for example, less than 0.5 mm, less than 0.3 mm, or less than 0.1 □m in thickness on the back surface of semiconductor wafer 1, without reducing the die strength of a chip, with preventing the permeation of the pollution impurities from the back surface of semiconductor wafer 1 simultaneously, the poor characteristic of the semiconductor element resulting from pollution impurities can be prevented. Thereby, a drop of the manufacture yield of semiconductor products can be suppressed. And in a back-grinding step, since a step which differs greatly is not added, the simplification of the process is possible.

In the above-mentioned back-grinding, although by grinding the back surface of semiconductor wafer 1 one by one using three grinding material of the first grinding material (for example, particle size of polish fine powder from #320 to #360), the second grinding material (for example, particle size of polish fine powder from #1500 to #2000), and the third grinding material (for example, particle size of polish fine powder from #3000 to #100000), semiconductor wafer 1 was made thin to the predetermined thickness (the fourth thickness) and the second crush layer 5 was further formed on the back surface of semiconductor wafer 1, the back surface of semiconductor wafer 1 can also be ground one by one using, for example two grinding material of the first grinding material (for example, particle size of polish fine powder from #320 to #360) and the third grinding material (for example, particle size of polish fine powder from #3000 to #100000). Thereby, the simplification of the back-grinding step is still more possible. The back-grinding which used two grinding material of the first grinding material (for example, particle size of polish fine powder from #320 to #360) and the third grinding material (for example, particle size of polish fine powder from #3000 to #100000) is explained below.

First, by performing rough grinding to the back surface of semiconductor wafer 1 like the rough grinding which used the first grinding material 3 mentioned above, the thickness of semiconductor wafer 1 is made to decrease to the predetermined thickness (the second thickness).

Then, the back surface of semiconductor wafer 1 is performed fine finish grinding. After performing vacuum adsorption of the circuit formation surface of semiconductor wafer 1 here at a chuck table using the same grinder equipment as the FIG. 2, by performing fine finish grinding pressing the rotating third grinding material to the back surface of semiconductor wafer 1, the thickness of semiconductor wafer 1 is made to decrease to the predetermined thickness (the fourth thickness). Since finish grinding using the second grinding material (for example, particle size of polish fine powder from #1500 to #2000) mentioned above is not performed, the semiconductor wafer 1 is ground by, for example about 25-40 □m by this fine finish grinding, and the fourth thickness of semiconductor wafer 1 becomes, for example less than 100 □m, less than 80 □m, or less than 60 □m. On the back surface of semiconductor wafer 1, the second crush layer 5 of the thickness of, for example less than 0.5 □m, less than 0.3 □m, or less than 0.1 □m is formed.

Next, after semiconductor wafer 1 is washed and dryed (washing/drying step P5 of FIG. 1), as shown in FIG. 6, semiconductor wafer 1 is stuck on dicing tape DT1 again (wafer mounting step P6 of FIG. 1). First, vacuum adsorption of the semiconductor wafer 1 is performed by a wafer transport jig, and it transports to wafer mounting equipment, as it is. Semiconductor wafer 1 transported by wafer mounting equipment is sent to an alignment portion, alignment of a notch or an orientation-flat is performed, after that, semiconductor wafer 1 is sent to a wafer mounting portion, and wafer mounting is performed. In wafer mounting, annular frame 6 which stuck dicing tape DT1 beforehand is prepared, and that circuit formation surface being the upper surface, semiconductor wafer 1 is stuck to this dicing tape DT1. Dicing tape DT1 uses polyolefin as a base material, for example, an acrylics system UV hardening type adhesive is applied, and the peeling material which includes polyester is further stuck on it. Peeling material is a mold-releasing paper, for example, the peeling material is removed and dicing tape DT1 is stuck on semiconductor wafer 1. The thickness of dicing tape DT1 is 90 □m, for example, and adhesive power is, for example 200 g/25 mm before UV irradiation and 10 to 20 g/25 mm after UV irradiation. There is no peeling material and the dicing tape about which mold-releasing-processing is done to the back surface of the substrate may be used.

Subsequently, frame 6 equipped with semiconductor wafer 1 is sent to an adhesive tape peeling portion. Here, semiconductor wafer 1 and adhesive tape BT1 peel. Thus, the reason to restick semiconductor wafer 1 on frame 6 is because it is necessary to use as the upper surface the circuit formation surface in which the alignment mark is formed to perform dicing at a later dicing step on the basis of the alignment mark currently formed in the circuit formation surface of semiconductor wafer 1. Since semiconductor wafer 1 is fixed via dicing tape DT1 stuck on frame 6 even if adhesive tape BT1 peels, the curvature of semiconductor wafer 1 does not surface.

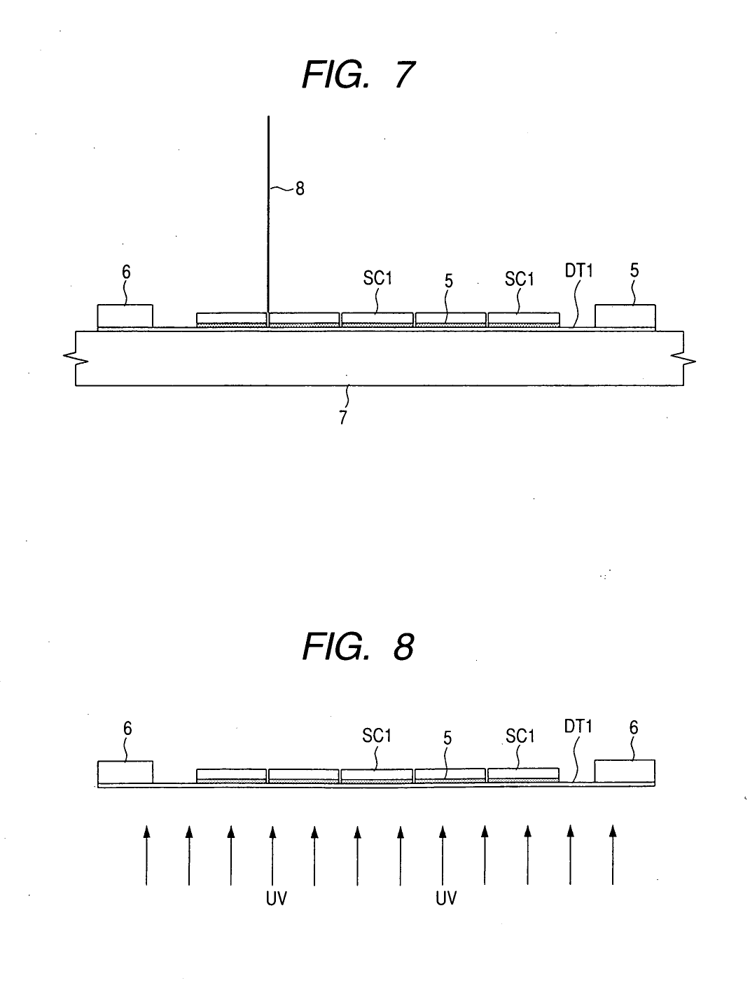

Next, as shown in FIG. 7, dicing of the semiconductor wafer 1 is performed (dicing step P7 of FIG. 1). Although semiconductor wafer 1 is individually separated by chip SC1, even after individually separating, since it is being fixed to frame 6 via dicing tape DT1, each chip SC1 is maintaining the state where it aligned. First, vacuum adsorption of the circuit formation surface of semiconductor wafer 1 is performed by a wafer transport jig, and semiconductor wafer 1 is transported to dicing equipment as it is, and is laid on dicing table 7. Then, semiconductor wafer 1 is cut lengthways and sideways along with a scribe-line using ultra-thin circular blade 8 which is called a diamond saw and which stuck the diamond particle (as for division of a wafer, the method which uses laser may be used. In that case, there is an additional merit, such as making width of cut very small.).

Next, as shown in FIG. 8, UV is irradiated on semiconductor wafer 1 (UV irradiation step P8 of FIG. 1). UV is irradiated from the back side of dicing tape DT1, and the adhesive power of the surface of dicing tape DT1 to touch each chip SC1 is reduced, for example to about 10 to 20 g/25 mm. Thereby, each chip SC1 separates easily from dicing tape DT1.

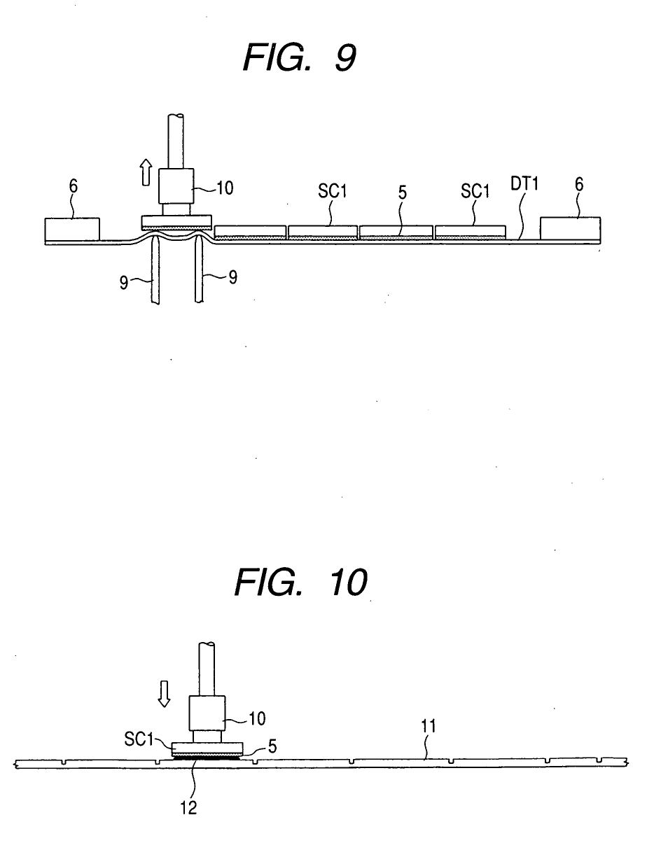

Next, as shown in FIG. 9, chip SC1 judged to be good in wafer test step P2 of FIG. 1 is picked up (picking-up step P9 of FIG. 1). First, the back surface of chip SC1 is pushed and pressed via dicing tape DT1 by pushing—up pin 9, and this peels chip SC1 from dicing tape DT1. Then, by collet 10 moving and being located in the upper part opposite to pushing-up pin 9, and doing vacuum adsorption by collet 10 to the circuit formation surface of chip SC1 which peeled, chip SC1 is torn off and picked up one at a time from dicing tape DT1. Since the adhesive strength of dicing tape DT1 and chip SC1 can be weakening by UV irradiation, even if it is chip SC1 to which strength is falling thinly, it can pick up certainly. Collet 10 has an outside of a rough cylinder type, for example, and the adsorption portion located in the bottom comprises an elastic synthetic rubber etc., for example.

Next, as shown in FIG. 10, chip SC1 used as the first stage is mounted on substrate 11 (die-bonding step P10 of FIG. 1).

First, chip SC1 picked up is adsorbed and held by collet 10, and is transported in the predetermined position on substrate 11. Then, paste material 12 is carried on the plated island (chip mounting area) of substrate 11, chip SC1 is pressed here lightly, and hardening processing is performed with the temperature of about 100 to 200° C. This sticks chip SC1 on substrate 11. As paste material 12, epoxy system resin, polyimide system resin, acrylics system resin, or silicone system resin can be exemplified. Except for the attachment by paste material 12, the back surface of chip SC1 is rubbed against the plated island lightly, or inserting the bit of a gold tape between the island and chip SC1 and making the eutectic crystal of gold and silicon, adhesion may be done.

After the die bonding of an good chip and the removal of a defective chip which were stuck by dicing tape DT1 are completed, dicing tape DT1 is removed from frame 6, and frame 6 is recycled.

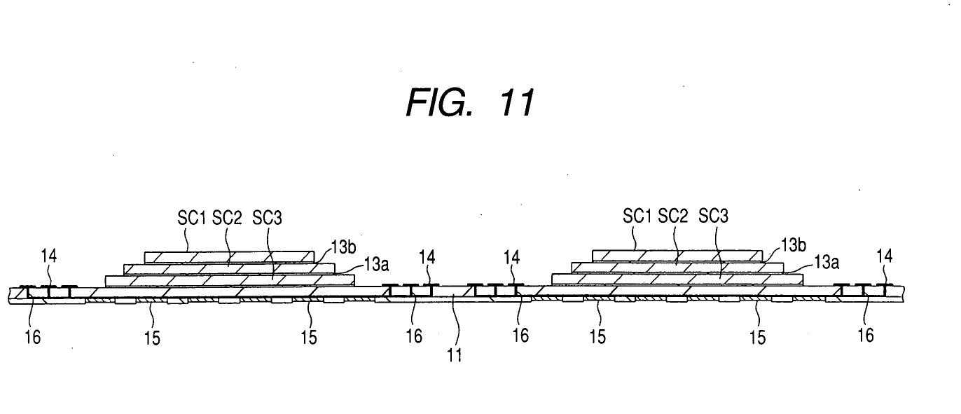

Next, as shown in FIG. 11, chip SC2 is prepared like the chip SC1, and chip SC2 which becomes the second stage is connected on chip SC1 of the first stage using, for example insulating paste 13a, then, by preparing chip SC3 like the chip SC1 and connecting chip SC3 which becomes the third stage on chip SC2 of the second stage using, for example insulating paste 13b, chip SC1, SC2, and SC3 are laminated. As for chip SC1 of the first stage, for example a microcomputer, as for chip SC2 of the second stage, for example an electrically batch erasing type EEPROM (Electric Erasable Programmable Read Only Memory), and as for chip SC3 of the third stage, for example an SRAM is exemplified. A plurality of electrode pads 14 are formed in the surface, a plurality of connection pads 15 are formed in the back surface of this substrate 11, and both are electrically connected by wiring 16 in a substrate.

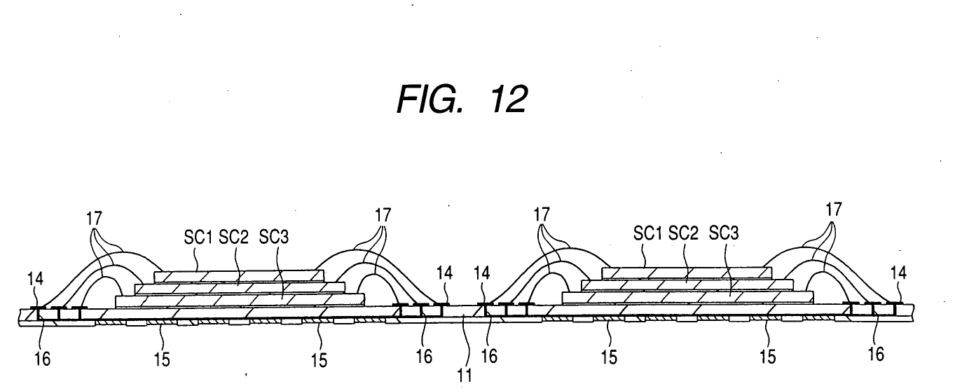

Next, as shown in FIG. 12, the bonding pad arranged on the border of the surface of each chip SC1, SC2, or SC3 and electrode pad 14 of the surface of substrate 11 are connected using bonding wire 17 (wire bonding step P11 of FIG. 1). The work is automated and done using bonding equipment. The arrangement information of the bonding pad of laminated chip SC1, SC2, and SC3 and electrode pad 14 of the surface of substrate 11 is beforehand inputted into bonding equipment, the relative location relation among laminated chip SC1, SC2, and SC3 mounted on substrate 11, the bonding pad of the surface, and electrode pad 14 of the surface of substrate 11 is taken in as a picture, data processing is performed, and bonding wire 17 is connected correctly. Under the present circumstances, the loop form of bonding wire 17 is controlled in the form which rose to be unable to touch the circumference portion of laminated chip SC1, SC2, and SC3.

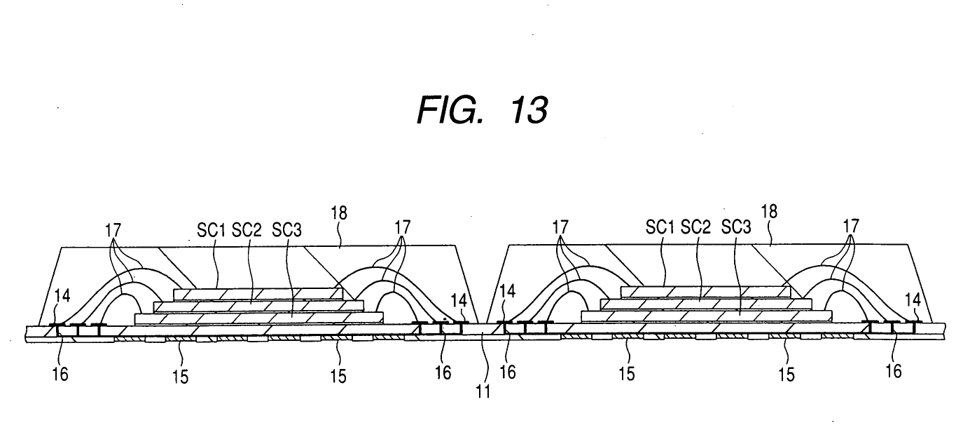

Next, as shown in FIG. 13, substrate 11 to which bonding wire 17 was connected is set to a metallic molding machine, resin 18 which was raised in temperature and liquefied is pressurized and sent and poured in, laminated chip SC1, SC2, and SC3 are enclosed, and mold forming is performed (molding step 12 of FIG. 1). Then, excessive resin 18 or excessive burr is removed.

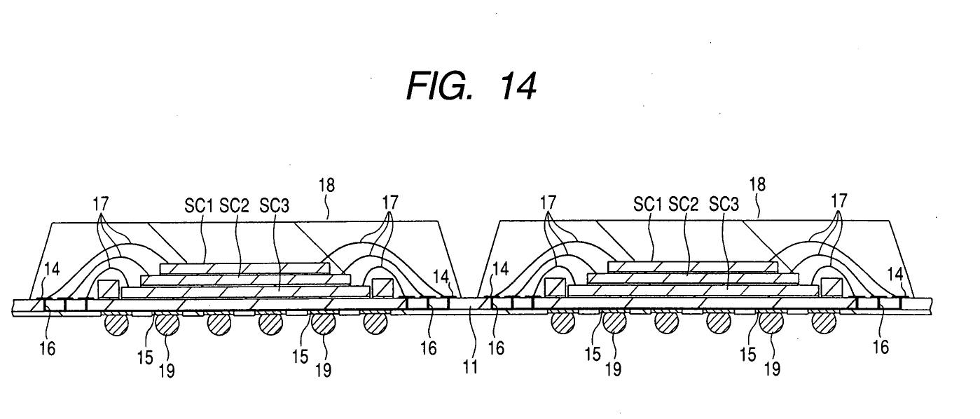

Next, as shown in FIG. 14, after supplying bump 19 including, for example solder to connection pad 15 of the back surface of substrate 11, performing reflow processing, bump 19 is melted, and bump 19 and connection pad 15 are connected (bump formation step P13 of FIG. 1).

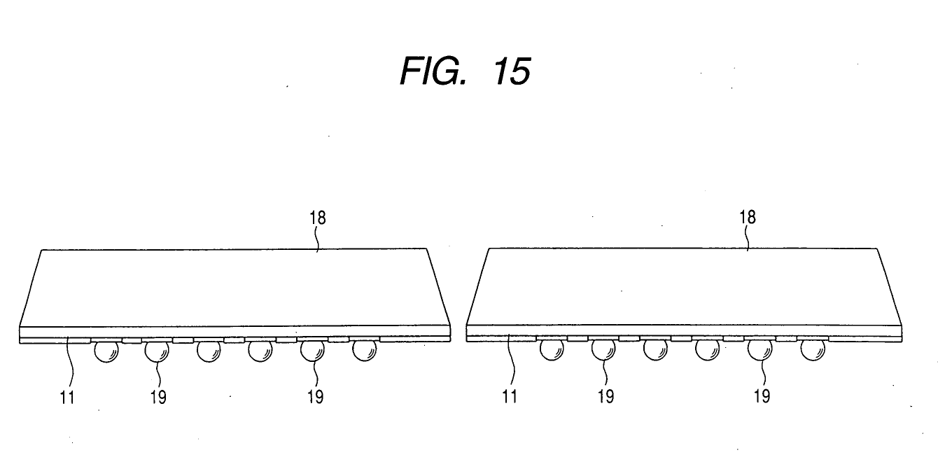

Then, as shown in FIG. 15, on resin 18, a name of article etc. is sealed and each laminated chip SC1, SC2, and SC3 is carved from substrate 11 (cutting step P14 of FIG. 1). Then, the finished product including each laminated chip SC1, SC2, and SC3 is sorted out according to product specifications, and passing an inspection step, a product is completed (assembling step P15 of FIG. 1).

Next, an example which performs continuous processing from back-grinding (step P4 of FIG. 1) to wafer mounting (step P6 of FIG. 1) being the Embodiment 1 is explained using the explanatory diagram of the consistent processing unit, shown in FIG. 16.

Consistent processing unit BGM1 shown in FIG. 16 includes a back grinder portion, a washing portion, and a wafer mounting portion. Each part is equipped with loader 20 which carries in and unloader 21 to carry out semiconductor wafer 1, and each part can also be used as a stand-alone. Between the back grinder portion and the washing portion, transport robot 22 which transports semiconductor wafer 1 between both is equipped, and between the washing portion and the wafer mounting portion, transport robot 23 which transports semiconductor wafer 1 between both is similarly equipped.

First, after putting the FOUP carrying a plurality of semiconductor wafers 1 on loader 20 of the back grinder portion, one semiconductor wafer 1 is picked out from the FOUP by transport robot 24 and carried in to processing room R1 of the back grinder portion. A FOUP is a sealing storage container for batch transport of semiconductor wafer 1, and usually stores semiconductor wafer 1 in batch units, such as 25 sheets, 12 sheets, and 6 sheets etc. The container outer wall of a FOUP has airtight structure except for the detailed ventilation filter portion, and dust is eliminated nearly completely. Therefore, even if it transports in the atmosphere of class 1000, the inside can maintain the cleanliness factor of class 1. By the robot of the equipment side drawing the door of a FOUP in the inside of the equipment, docking to equipment is performed where cleanliness is held.

Next, after laying semiconductor wafer 1 on chuck table 25 and performing vacuum adsorption, performing rough grinding to the back surface of semiconductor wafer 1 using the first grinding material, the thickness of semiconductor wafer 1 is made to decrease to the predetermined thickness (the second thickness). Then, performing finish grinding to the back surface of semiconductor wafer 1 using the second grinding material, the thickness of semiconductor wafer 1 is made to decrease to the predetermined thickness (the third thickness). Then, performing fine finish grinding to the back surface of semiconductor wafer 1 using the third grinding material, the thickness of semiconductor wafer 1 is made to decrease to the predetermined thickness (the fourth thickness), and the second crush layer 5 is further formed on the back surface of semiconductor wafer 1. Here, although grinding which used the first, second, and third grinding material was performed, finish grinding using the second grinding material may be omitted.

Next, after the back grinder of semiconductor wafer 1 finishes, semiconductor wafer 1 being carried out from the back grinder portion and transported to the washing portion by transport robot 22, and further carrying in semiconductor wafer 1 to processing room R2 of the cleaning portion by transport robot 26, washing by pure water and drying of semiconductor wafer 1 are performed. Then, after semiconductor wafer 1 being carried out from the washing portion and transported to the wafer mounting portion by transport robot 23, and performing vacuum adsorption of the back surface of semiconductor wafer 1 with transport robot 27, the vacuum adsorption surface of semiconductor wafer 1 is changed, and vacuum adsorption of the circuit formation surface is performed. Then, semiconductor wafer 1 is carried in to processing room R3 of the wafer mounting portion. Here, after sticking semiconductor wafer 1 on the dicing tape stuck and fixed to the annular frame making the circuit formation surface an upper surface, semiconductor wafer 1 is stuck on the dicing tape making the circuit formation surface the upper surface, and adhesive tape BT1 is peeled. Then, semiconductor wafer 1 is transported to unloader 21 of the wafer mounting portion, semiconductor wafer 1 is taken out from the wafer mounting portion, and it returns to a FOUP again.

Thus, by using consistent processing unit BGM1, semiconductor wafer 1 can be processed from back-grinding to wafer mounting in a short time.

### EMBODIMENT 2

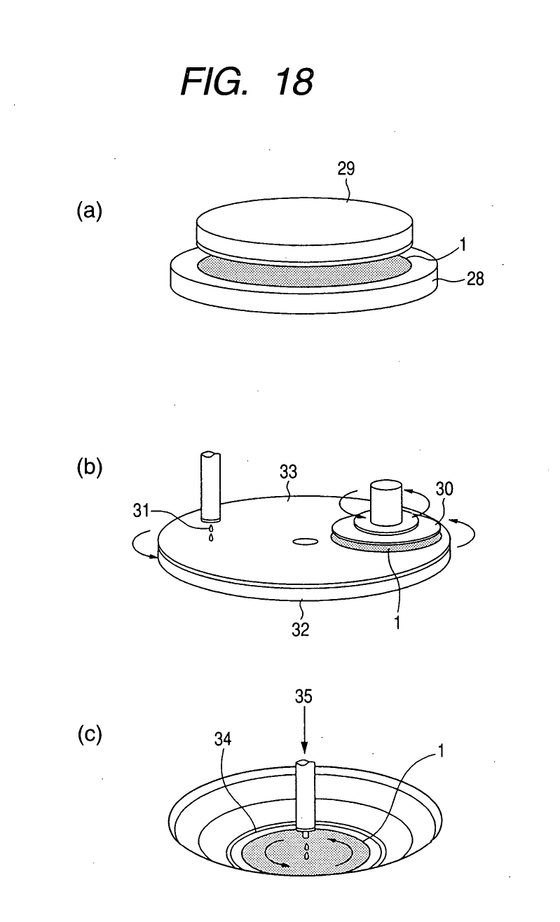

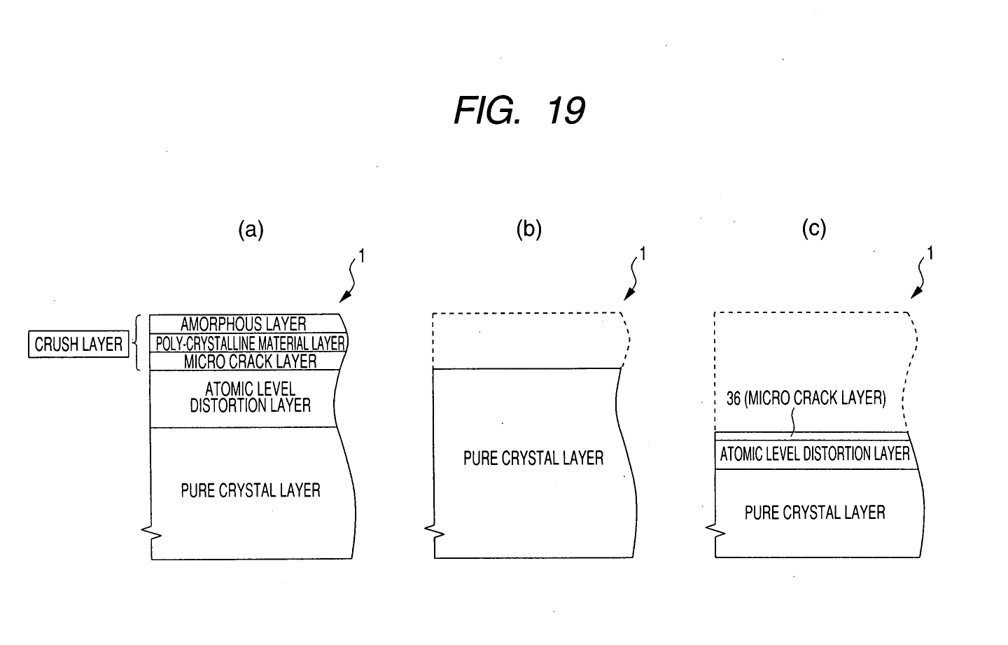

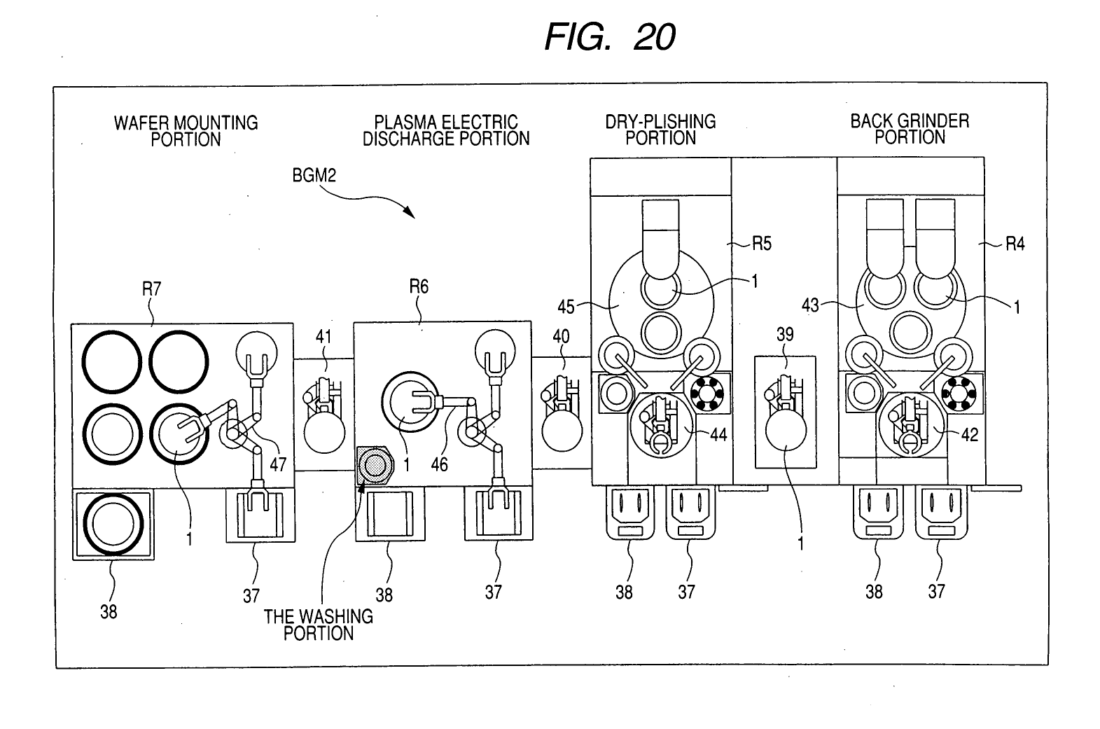

The manufacturing method of the semiconductor integrated circuit device by the Embodiment 2 is explained in order of a step using from FIG. 17 to FIG. 19. FIG. 17 is a flowchart of the manufacturing method of a semiconductor integrated circuit device; FIG. 18 is an explanatory diagram of a stress relief system; FIG. 19 is a principal part expanded sectional view of the back side portion of a semiconductor wafer; and FIG. 20 is an explanatory diagram of a consistent processing unit used from back-grinding to wafer mounting. The same steps as the Embodiment 1, namely, from the integrated circuit formation step to the adhesive tape sticking step, and from the washing/drying step to the assembling step are omitted, and the following explanation explains each step from a back-grinding step to a crush layer formation step.

First, grinding the back surface (the surface of the opposite side to the circuit formation surface, the second main surface) of semiconductor wafer 1, the thickness of semiconductor wafer 1 shall be predetermined thickness, for example, less than 100 □m, less than 80 □m, or less than 60 □m (back-grinding step P4 of FIG. 17). In this back-grinding, rough grinding and finish grinding are performed one by one like the Embodiment 1. Namely, after, by performing rough grinding pressing the rotating first grinding material (for example, particle size of polish fine powder from #320 to #360) 3 to the back surface of semiconductor wafer 1, the thickness of semiconductor wafer 1 is made to decrease to the predetermined thickness (the second thickness), by performing finish grinding pressing the rotating second grinding material (for example, particle size of polish fine powder from #1500 to #2000) to the back surface of semiconductor wafer 1, the warp of the back surface of semiconductor wafer 1 generated at the time of the above-mentioned rough grinding is removed.

Although an atomic level distortion layer and the first crush layer (an amorphous layer/poly-crystalline material layer/micro crack layer; the first layer) 4 are formed on the pure crystal layer of the back surface of semiconductor wafer 1 in the above-mentioned back-grinding, stress relief removes the first crush layer 4 (stress relief step P5 of FIG. 17). The thickness of the first crush layer 4 is about 1 to 2 □m, for example, and can raise the die strength of a chip by removing this first crush layer 4. When removing the first crush layer 4, a part of atomic level distortion layer may be removed.

First, vacuum adsorption of the back surface of semiconductor wafer 1 by which vacuum adsorption was performed in the circuit formation surface at the chuck table of the grinder equipment which performed finish grinding is performed by a wafer transport jig, and by cutting the vacuum of a chuck table, semiconductor wafer 1 is held by a wafer transport jig, and semiconductor wafer 1 is transported to stress relief equipment as it is. Stress relief is given after vacuum adsorption of the semiconductor wafer 1 is performed in the circuit formation surface at the rotating table or the pressurization head of the stress relief equipment.

In this stress relief, as shown, for example in FIG. 18, a dry-polishing method (FIG. 18 (a)), the CMP method (FIG. 18 (b)), or a chemical-etching method (FIG. 18 (c)) is used. The dry-polishing method is the method to polish the back surface of semiconductor wafer 1 placed on rotating table 28 with abrasive cloth (cloth on which silica was made to adhere by binder on the Surface of a fiber, and which was hardened in the shape of a pad to be, for example about φ400 mm and about 26 mm thick:Dry Polish Wheel) 29 to which the abrasive particle adhered. This dry-polishing method can make cost cheaper than other methods. A CMP method is the method to make stick the back surface of semiconductor wafer 1 to scouring pad 33 stuck on the surface of platen (surface table) 32 by pressure, and to grind, holding semiconductor wafer 1 with pressurization head 30, and passing slurry (polish abrasive particle liquid) 31. This CMP method can acquire a uniform processing surface. A chemical-etching method is the method to, carrying semiconductor wafer 1 on rotating table 34, etch using mixed-solution of fluoric acid and nitric acid (HF+HNO₃) 35. This chemical-etching method has the advantage that there are many amounts of removal.

Next, as shown in FIG. 19, the third crush layer (micro crack layer; the third layer) 36 is formed in the back surface of semiconductor wafer 1 (crush-layer-forming step P6 of FIG. 17). FIG. 19 is a principal part sectional view of the back side portion of semiconductor wafer 1, and FIGS. 19 (a), (b), and (c) show semiconductor wafer 1 performed rough grinding using the first grinding material, semiconductor wafer 1 given stress relief, and semiconductor wafer 1 in which the third crush layer 36 was formed, respectively. After stress relief finished, in the case where the first crush layer 4 formed in the back surface of semiconductor wafer 1 by finish grinding was removed and a pure silicon crystal structure portion is exposed, if pollution impurities, for example heavy metal impurities etc., adhere to the back surface of semiconductor wafer 1, they will infiltrate into semiconductor wafer 1 easily. Then, the back surface of semiconductor wafer 1 is again ground in a very small quantity, as shown in FIG. 19 (c), the third crush layer 36 is formed, and permeation and diffusion of the pollution impurities to semiconductor wafer 1 are suppressed by this third crush layer 36. In FIG. 19 (c), the state where the atomic level distortion layer and the third crush layer 36 were formed on the pure crystal layer is exemplified. At the Embodiment 2, this third crush layer is formed only by the micro crack layer. Thus, since the third crush layer 36 is formed only by the micro crack layer, the die strength of a chip can be improved rather than the case of the Embodiment 1.

This third crush layer 36 is, for example a micro crystal defective layer, and as for the thickness, for example less than 0.5 □m (that is, it is more advantageous to be comparatively thicker in order to secure the die strength of a chip) is considered to be a suitable range (naturally depending on other conditions, not limited to this range). Although less than 0.3 □m can be considered as a range suitable for mass production, it is thought that the range of less than 0.1 □m (it is because it is satisfactory if it is more than the lower limit which can prevent permeation and diffusion of pollution impurities) is the most preferred.

Formation of the third crush layer 36 is performed by either of the first to fifth method of describing below, for example. Here, stress relief being carried out, the die strength of a desired chip is secured, and after that the third crush layer 36 which is given gettering capability by giving the moderate damage of a grade which does not drop the die strength of a chip to the back surface of semiconductor wafer 1 is explained.

First, vacuum adsorption of the semiconductor wafer 1 to which vacuum adsorption was performed at the rotating table or pressurization head of stress relief equipment is performed by a wafer transport jig, by cutting the vacuum of a rotating table or a pressurization head, semiconductor wafer 1 is held by a wafer transport jig, and semiconductor wafer 1 is transported to a crush layer formation equipment as it is. Vacuum adsorption of the semiconductor wafer 1 transported to the crush layer formation equipment is performed in the circuit formation surface at the chuck table of crush layer formation equipment etc., for example, and the third crush layer 36 is formed in the back surface.

By the first method, a micro crystal defective layer (a micro crack layer, the third crush layer 36) is formed in the back surface of semiconductor wafer 1 by sandblasting. First, the back surface of semiconductor wafer 1 is exposed and masking material is formed. The resist pattern formed, for example by the lithography technology can be used for masking material. Then, injecting abrasive particles with the gas which is pressurized about 2 to 3 kgf/cm², for example, the back surface of semiconductor wafer 1 is washed, and the third crush layer 36 is further formed in the washed back surface. Grains are SiC and alumina, for example and the particle diameter is roughly from a few to several hundred □m, for example. Then, masking material is removed and semiconductor wafer 1 is washed.

By the second method, ion is generated by plasma electric discharge, for example, and a micro crystal defective layer, i.e., a damage layer (a micro crack layer, the third crush layer 36), is formed in the back surface of semiconductor wafer 1 by impacting this ion. As plasma conditions, gas in use CF₄ or SF₆, degree of vacuum from 1 to 1.8 Torr (from 133.322 to 239.980 Pa), temperature from 15 to 20° C., and time about 1 minute, or gas in use Cl, degree of vacuum from 20 to 50 mTorr (2666.45 to 6666.12 mPa), temperature from 15 to 20° C., and time about 1 minute can be exemplified, and with these conditions, the damage layer whose thickness is roughly from 2 to 10 nm, for example is formed. By this formation method of the damage layer by plasma, plasma can wash the back surface of semiconductor wafer 1. There is an advantage that a damage layer is formed in the washed back surface of semiconductor wafer 1, and simultaneously the insulated film (for example, oxide film) or auxiliary film as the barrier layer which can prevent pollution impurities invading from the surface of a damage layer, or a fissility improvement layer can be formed in it.

By the third method, without removing the first crush layer 4 altogether, in stress relief, it leaves a part of first crush layer 4, and this is used as a micro crystal defective layer (the third crush layer 36).

By the fourth method, after stress relief, a fine mesh grinding wheel is used, for example, the back surface of semiconductor wafer 1 is again ground in a very small quantity, and a micro crystal defective layer (the third crush layer 36) is formed. In this case, the third crush layer 36 comprises an amorphous layer/a poly-crystalline material layer/a micro crack layer like the second crush layer 5 of the Embodiment 1 (refer to the FIG. 4).

By the fifth method, after stress relief, laser light is irradiated, for example and a micro crystal defective layer (the third crush layer 36) is formed in the back surface of semiconductor wafer 1. Although a chip back surface is processed (carved) with equipment, such as a laser marker, by condensing laser light at a minute spot and scanning this by arbitrary loci, by the principle same with naturally a crystal defective layer being made under the present circumstances, by suitably dropping laser light strength, or, for example by expanding irradiation area by an expansion optical system (lens system) etc., the laser light of the optimal energy can be irradiated and scanned and a necessary minimum micro crystal defective layer (the third crush layer 36) can be formed in a wafer back surface.

The purpose of the Embodiment 2 is attained by re-forming a micro crystal defective layer (the third crush layer 36) not only by these but by a certain method after stress relief.

Thus, according to the Embodiment 2, although the first crush layer (for example, less than 2 □m, less than 1 □m, or less than 0.5 □m in thickness) 4 on the back surface of semiconductor wafer 1 which was formed by the back-grinding was removed by stress relief in order to raise the die strength of a chip and the atomic level distortion layer is exposed, by grinding again the back surface of the semiconductor wafer 1 in a very small quantity and forming the third crush layer (for example, less than 0.5 □m, less than 0.3 □m, or less than 0.1 □m in thickness) 36 (or leaving a part of first crush layer 4), without reducing the die strength of a chip, permeation of the pollution impurities from the back surface of semiconductor wafer 1 can be prevented simultaneously, diffusion of the pollution impurities to the circuit formation surface of semiconductor wafer 1 can be prevented further, and the poor characteristic of the semiconductor element resulting from pollution impurities can be prevented. Thereby, a drop of the manufacture yield of semiconductor products can be suppressed. Especially, as mentioned above, in the Embodiment 2, since the third crush layer 36 is formed only by the micro crack layer, the die strength of a chip can be improved rather than the case of the Embodiment 1. By the way, since the atomic level distortion layer is considered as the structure which has a plurality of detailed distortion, this atomic level distortion layer also has the above-mentioned gettering function. That is, the structure (state where the atomic level distortion layer is exposed to the back surface of semiconductor wafer 1) that only the atomic level distortion layer is formed on the pure crystal layer of the back surface of semiconductor wafer 1 can also prevent invasion of pollution impurities. And yet, since a crush layer is very thin or does not exist substantially, the die strength of a chip can be improved further.

Then, like the Embodiment 1, by passing washing/drying step P7, wafer mounting step P8, dicing step P9, UV irradiation step P10, picking-up step P11, die-bonding step P12, etc. one by one, for example the product shown in the FIG. 15 is completed.

Next, an example which performs continuous processing of from a back-grinding (step P4 of FIG. 17) to wafer mounting (step P8 of FIG. 17) being the Embodiment 2 is explained using the diagram of the consistent processing unit shown in FIG. 20.

Consistent processing unit BGM2 shown in FIG. 20 includes a back grinder portion, a dry-polishing portion, a plasma electric discharge portion, and a wafer mounting portion. Although the dry-polishing method was exemplified to stress relief here, the CMP method or a chemical-etching method may be used. Although plasma electric discharge (the second method of the above) was exemplified to formation of the third crush layer 36 here, other systems which form the third crush layer 36 may be used. For example, a plasma electric discharge portion can be transposed to a sandblasting portion, a fine mesh grinding wheel portion, etc. In this consistent processing unit BGM2, the washing portion is provided in the wafer outgo area of the plasma electric discharge portion.

Each part is equipped with loader 37 to carry in, and unloader 38 to carry out semiconductor wafer 1, and each part can also be used as a stand-alone. Between the back grinder portion and the dry-polishing portion, transport robot 39 to transport semiconductor wafer 1 between both is equipped, and similarly between the dry-polishing portion and the plasma electric discharge portion and between the plasma electric discharge portion and the wafer mounting portion, transport robots 40 and 41 to transport semiconductor wafer 1 between both, respectively are equipped.

First, after putting the FOUP carrying a plurality of semiconductor wafers 1 on loader 37 of a back grinder portion, one semiconductor wafer 1 is picked out from a FOUP by transport robot 42, and is carried in to processing room R4 of a back grinder portion. Then, after laying semiconductor wafer 1 on chuck table 43 and performing vacuum adsorption, the back surface of semiconductor wafer 1 being performed rough grinding, the thickness of semiconductor wafer 1 is made to decrease to the predetermined thickness (the second thickness). Then, the back surface of semiconductor wafer 1 being performed finish grinding using the second grinding material, the thickness of semiconductor wafer 1 is made to decrease to the predetermined thickness (the third thickness). Here, the first crush layer 4 is formed in the back surface of semiconductor wafer 1.

Next, after the back-grinding of semiconductor wafer 1 finishes, semiconductor wafer 1 being carried out from a back grinder portion by transport robot 39 and transported to a dry-polishing portion, semiconductor wafer 1 is further carried in to processing room R5 of a dry-polishing portion by transport robot 44. After laying semiconductor wafer 1 on chuck table 45 and performing vacuum adsorption, the first crush layer 4 is removed from the back surface of semiconductor wafer 1.

Next, after the dry-polishing of semiconductor wafer 1 finishes, semiconductor wafer 1 being carried out from a dry-polishing portion by transport robot 40 and transported to a plasma electric discharge portion, semiconductor wafer 1 is further carried in to processing room R6 of a plasma electric discharge portion by transport robot 46. Here, a micro crystal defective layer (the third crush layer 36) is formed in the back surface of semiconductor wafer 1.

Next, when washing of semiconductor wafer 1 by the pure water finishes at the washing portion provided in the outgo area of the plasma electric discharge portion, after semiconductor wafer 1 being carried out from a plasma electric discharge portion by transport robot 41, transported to a wafer mounting portion, and performed vacuum adsorption of the back surface of semiconductor wafer 1 with transport robot 47, the vacuum adsorption surface of semiconductor wafer 1 is changed, and vacuum adsorption of the circuit formation surface is performed. Then, semiconductor wafer 1 is carried in to processing room R7 of a wafer mounting portion. Here, after sticking semiconductor wafer 1 on the dicing tape stuck and fixed to the annular frame using the circuit formation surface as the upper surface, semiconductor wafer 1 is stuck on a dicing tape using the circuit formation surface as the upper surface, and adhesive tape BT1 is peeled. Then, semiconductor wafer 1 is transported to unloader 38 of a wafer mounting portion, semiconductor wafer 1 is taken out from a wafer mounting portion, and it returns to a FOUP.

Thus, semiconductor wafer 1 can be processed from a back-grinding to wafer mounting by using consistent processing unit BGM2 in a short time, and after stress relief, since the third crush layer 36 is continuously formed in the back surface of semiconductor wafer 1, permeation of the pollution impurities from the back surface of semiconductor wafer 1 can be prevented.

Although the Embodiments 1 and 2 were indicated in another section, respectively, it cannot be overemphasized that, technically saying, the former and the latter relate mutually and closely instead of being completely separate inventions, and, for example the latter purpose is attained in the former example in many cases. Although not indicated in detail, it cannot be overemphasized that applying the measure against former and the measure against latter together is included in the embodiments. It cannot be overemphasized that applying the similar measure in the former or in the latter (or in the both sides) together is included.

As mentioned above, although inventions made by the inventor were concretely explained based on the embodiments of inventions, it cannot be overemphasized that the invention is not limited to the embodiment and it can be changed variously in the range which does not deviate from the gist.

For example, although the first to fifth method was exemplified by the Embodiment 2 as a method of forming a crush layer in the back surface of a semiconductor wafer, it is not limited to this and other technology which can prevent permeation of the pollution impurities from the back surface of a semiconductor wafer can be applied.

### INDUSTRIAL APPLICABILITY

The invention is performed after the front-end process to form a circuit pattern on a semiconductor wafer and inspects a chip one by one, and it can apply to the back-end process to assemble a chip for a product.

1. A manufacturing method of a semiconductor integrated circuit device, comprising the steps of:
(a) forming a circuit pattern over a first main surface of a semiconductor wafer that has a first thickness;
(b) making the semiconductor wafer a second thickness by grinding a second main surface of the semiconductor wafer using a first grinding material which has a fixed abrasive;
(c) making the semiconductor wafer a fourth thickness and forming a second crush layer in the second main surface of the semiconductor wafer by grinding the second main surface of the semiconductor wafer using a third grinding material which has a fixed abrasive a diameter of a particle of which is smaller than the first grinding material; and
(d) individually separating the semiconductor wafer to a chip by dicing the semiconductor wafer;
wherein a particle size of a polish fine powder of the third grinding material is #3000 to #100000.

2. A manufacturing method of a semiconductor integrated circuit device according to claim 1, wherein
a particle size of a polish fine powder of the first grinding material is #100 to #700.

3. A manufacturing method of a semiconductor integrated circuit device according to claim 1, wherein
the particle size of the polish fine powder of the third grinding material is #4000 to #50000.

4. A manufacturing method of a semiconductor integrated circuit device according to claim 1, wherein
the particle size of the polish fine powder of the third grinding material is #5000 to #20000.

5. A manufacturing method of a semiconductor integrated circuit device according to claim 1, wherein
the particle size of the polish fine powder of the third grinding material is #8000 or more than it.

6. A manufacturing method of a semiconductor integrated circuit device according to claim 1, wherein
a thickness of the second crush layer is less than 1 □m.

7. A manufacturing method of a semiconductor integrated circuit device according to claim 1, wherein
a thickness of the second crush layer is less than 0.5 □m.

8. A manufacturing method of a semiconductor integrated circuit device according to claim 1, wherein
a thickness of the second crush layer is less than 0.1 □m.

9. A manufacturing method of a semiconductor integrated circuit device according to claim 1, wherein
the fourth thickness of the semiconductor wafer is less than 100 □m.

10. A manufacturing method of a semiconductor integrated circuit device according to claim 1, wherein
the fourth thickness of the semiconductor wafer is less than 80 □m.

11. A manufacturing method of a semiconductor integrated circuit device according to claim 1, wherein
the fourth thickness of the semiconductor wafer is less than 60 □m.

12. A manufacturing method of a semiconductor integrated circuit device according to claim 1, between the step (b) and the step (c), further comprising the step of:
(e) making the semiconductor wafer a third thickness thinner than the second thickness and thicker than the fourth thickness by grinding the second main surface of the semiconductor wafer using a second grinding material which has a fixed abrasive with a diameter of a particle smaller than the first grinding material and the diameter of the particle larger than the third grinding material.

13. A manufacturing method of a semiconductor integrated circuit device according to claim 12, wherein
a particle size of a polish fine powder of the second grinding material is #1500 to #2000.

14. A manufacturing method of a semiconductor integrated circuit device, comprising the steps of:
(a) forming a circuit pattern over a first main surface of a semiconductor wafer that has a first thickness;
(b) making the semiconductor wafer a second thickness by grinding a second main surface of the semiconductor wafer using a first grinding material which has a fixed abrasive;
(c) making the semiconductor wafer a third thickness and forming a first crush layer in the second main surface of the semiconductor wafer by grinding the second main surface of the semiconductor wafer using a second grinding material which has a fixed abrasive a diameter of a particle of which is smaller than the first grinding material;
(d) removing the first crush layer of the second main surface of the semiconductor wafer;
(e) forming a third crush layer in the second main surface of the semiconductor wafer; and
(f) individually separating the semiconductor wafer to a chip by dicing the semiconductor wafer.

15. A manufacturing method of a semiconductor integrated circuit device according to claim 14, wherein
a particle size of a polish fine powder of the first grinding material is #100 to #700.

16. A manufacturing method of a semiconductor integrated circuit device according to claim 14, wherein
a particle size of a polish fine powder of the second grinding material is #1500 to #2000.

17. A manufacturing method of a semiconductor integrated circuit device according to claim 14, wherein
a thickness of the third crush layer is less than 0.5 □m.

18. A manufacturing method of a semiconductor integrated circuit device according to claim 14, wherein
a thickness of the third crush layer is less than 0.3 □m.

19. A manufacturing method of a semiconductor integrated circuit device according to claim 14, wherein
a thickness of the third crush layer is less than 0.1 □m.

20. A manufacturing method of a semiconductor integrated circuit device according to claim 14, wherein
the third thickness of the semiconductor wafer is less than 100 □m.

21. A manufacturing method of a semiconductor integrated circuit device according to claim 14, wherein
the third thickness of the semiconductor wafer is less than 80 □m.

22. A manufacturing method of a semiconductor integrated circuit device according to claim 14, wherein
the third thickness of the semiconductor wafer is less than 60 □m.

23. A manufacturing method of a semiconductor integrated circuit device according to claim 14, wherein
the step (e) includes the following subordinate step of:
(e1) forming the third crush layer in the second main surface of the semiconductor wafer by injecting an abrasive particle to the second main surface of the semiconductor wafer.

24. A manufacturing method of a semiconductor integrated circuit device according to claim 14, wherein
the step (e) includes the following subordinate step of:
(e1) forming the third crush layer in the second main surface of the semiconductor wafer by impacting an ion produced by plasma electric discharge to the second main surface of the semiconductor wafer.

25. A manufacturing method of a semiconductor integrated circuit device according to claim 14, wherein
the step (e) includes the following subordinate step of:
(e1) forming the third crush layer in the second main surface of the semiconductor wafer by grinding the second main surface of the semiconductor wafer.

26. A manufacturing method of a semiconductor integrated circuit device according to claim 14, wherein
the step (d) includes the following step of:
(d1) making a left-behind first crush layer the third crush layer of the step (e) by removing the first crush layer formed in the second main surface of the semiconductor wafer leaving a part.
